(19) United States
(12) Patent Application Publication
(10) Pub. No.: US 2026/0269821 A1
(43) Pub. Date: Sep. 10, 2026

(54) DIFFERENTIATING METHOD OF MATHEMATICAL MODEL OF THREE-LEVEL CONVERTER CONSIDERING NEUTRAL POINT DYNAMICS

(71) Applicants: Guangxi Power Grid Co. LTD, Guangxi (CN); HUAZHONG UNIVERSITY OF SCIENCE AND TECHNOLOGY, Hubei (CN)

(72) Inventors: Hui Qin, Guangxi (CN); Jiabing Hu, Guangxi (CN); Yue Wu, Guangxi (CN); Jiali Kui, Guangxi (CN); Hengwang Zhou, Guangxi (CN); Yingbiao Li, Guangxi (CN); Kaiwen Huang, Guangxi (CN); Guojie Zhao, Guangxi (CN); Junjie Feng, Guangxi (CN); Zhaolin Zhang, Guangxi (CN); Zehao Wang, Guangxi (CN); Zefei Wu, Guangxi (CN); Buyang Du, Guangxi (CN); Zeren Guo, Guangxi (CN)

(73) Assignees: Guangxi Power Grid Co. LTD, Guangxi (CN); HUAZHONG UNIVERSITY OF SCIENCE AND TECHNOLOGY, Hubei (CN)

(21) Appl. No.: 19/078,285

(22) Filed: Mar. 13, 2025

(30) Foreign Application Priority Data
Mar. 4, 2025 (CN) 202510252008.5

(51) Int. Cl. H03K 17/13; G06F 30/20

(52) U.S. Cl. CPC H03K 17/13; G06F 30/20

(57) ABSTRACT

This disclosure relates to the field of power system, specifically disclosing a differentiating method of mathematical model of three-level converter considering neutral point dynamics. The disclosure firstly establishes the transformation relationship between the neutral point voltage and the neutral point current of the three-level converter. Then, based on the neutral point voltage, a dynamic model of the neutral point potential balance controller is established. Subsequently, an expression for the neutral point current of the three-level converter under the influence of the neutral point potential balance controller is constructed. Finally, a differentiating expression for the neutral point current of the three-level converter is obtained from the expression by using Fourier series. The technical solution of this disclosure achieves the differentiation of the neutral point dynamics of the three-level converter, facilitating linearization and stability analysis of power-electronized power systems.

### CROSS-REFERENCE TO RELATED APPLICATION

This application claims the priority benefit of China application no. 202510252008.5, filed on Mar. 4, 2025. The entirety of the above-mentioned patent application is hereby incorporated by reference herein and made a part of this specification.

### BACKGROUND

### Technical Field

The disclosure belongs to a technical field of power system, and more specifically, to a differentiating method of mathematical model of three-level converter considering neutral point dynamics.

### Description of Related Art

Under the background of the twin goals of carbon peak and carbon neutrality, the rapid development of renewable energy such as wind and photovoltaic power generation has imposed new demands on the power rating of converters. With the continuous increase in the single-unit capacity of renewable energy, three-level converters which are suitable for high-voltage and high-capacity applications have been widely adopted in the fields of wind and photovoltaic power generation. Concurrently, as power electronic devices are extensively utilized in power systems, power quality issues and harmonic pollution in AC grids have become increasingly severe. The three-level converter, by increasing the number of voltage levels, reduces the voltage stress on individual switching devices, thereby enabling higher voltage and power output. Moreover, due to its advantages of high power factor and low harmonic content, the three-level converter can effectively enhance power quality, transmission, and utilization efficiency.

However, as the proportion of large-scale renewable energy in the power grid continues to rise, the trend of electric power system becomes increasingly evident, leading to the emergence of stability in power systems. Simulation modeling is one of the key methods for analyzing the stability of power-electronized power systems. Currently, most modeling methods for grid-connected three-level converters overlook the dynamic process of the three-level neutral point, thus failing to reflect the internal characteristics of the three-level converter. Additionally, while some studies consider the neutral point dynamics in the mathematical model of the three-level converter, the control logic of the switching devices affects the averaging process of the neutral point current modulation. In the related averaged models, absolute value functions are used for processing, which inevitably introduces non-differentiable points, thereby challenging the stability analysis of the three-level converters in the power grid.

### SUMMARY

In view of defects in the related art, a purpose of the disclosure is to provide a differentiating method of mathematical model of three-level converter considering neutral point dynamics. The objective is to address the technical issue in current three-level converter mathematical models where non-differentiable points make the analysis of the physical characteristics of the three-level converter challenging.

To achieve the above objectives, in the first aspect, the disclosure provides a differentiating method of mathematical model of three-level converter considering neutral point dynamics, including:
Establishing the transformation relationship between the neutral point voltage and the neutral point current of the three-level converter;
based on the neutral point voltage, establishing a dynamic model of the neutral point potential balance controller;
constructing an expression for the neutral point current of the three-level converter under the influence of the neutral point potential balance controller;
expanding the expression using Fourier series to achieve differentiability of the neutral point in the three-level converter.

Preferably, the transformation relationship between the neutral point voltage and the neutral point current of the three-level converter is that the derivative of the neutral point voltage is equal to the neutral point current divided by the sum of the capacitance values of the upper and lower levels of the three-level converter.

Preferably, the neutral point potential balance controller generates a compensation amount through PI operation based on the neutral point potential error, and then superimposes the compensation amount onto the modulation wave to achieve neutral point potential balance control.

Preferably, the expression for the neutral point current of the three-level converter is constructed based on the output current of the three-level converter, the output of the neutral point potential balance controller, the three-phase modulation wave, and the power factor angle.

Preferably, the three-phase modulation wave in the expression for the neutral point current of the three-level converter is expanded using Fourier series to achieve differentiability of the neutral point in the three-level converter.

Preferably, the neutral point potential balance controller is specifically:

$${m}_{0} = \frac{( {k}_{ipn} ( 0 - {u}_{pn} ) + {x}_{v} )}{{u}_{dc}}$$

Where m₀ is the output of the neutral potential balance controller; \dot{x}ᵥ is the output of a PI integral controller, \dot{x}ᵥ=kₚₚₙ(0−uₚₙ), \dot{x}ᵥ is the derivative of xᵥ; uₚₙ is the neutral voltage, and u_{dc} is the DC voltage. kₚₚₙ is the proportional gain coefficient of neutral potential balance control, and kᵢₚₙ is the integral adjustment coefficient of neutral potential balance control.

Preferably, the expression of the neutral point current iₚₙ of the three-level converter is as follows:

$${i}_{pn} = {\sum }_{j = a , b , c} ( 1 - \vert {m}_{j} \vert ) {i}_{j} - \frac{6}{π} {m}_{0} \sqrt{{i}_{d}^{2} + {i}_{q}^{2}} cos φ$$

Where, i_{d} represents the output current of the D-axis of the three-level converter, and i_{q} represents the output current of the Q-axis of the three-level converter; iⱼ, j=a, b, c indicates the output current of phase a, b, or c of the three-level converter; π is PI; φ is the power factor angle; mⱼ, j=a, b, c represents an a, b, or c phase modulation wave of a three-level converter; m₀ is the output of the neutral potential balance controller.

Preferably, expanding Fourier series on the three-phase modulation wave in the expression, specifically, expanding the three-phase modulation wave using Fourier series:

$$\vert {m}_{j} \vert \approx {S}_{jpn} = \frac{{a}_{0}}{2} + \frac{1}{π} {\sum }_{n = 1}^{N} ( cos ( n {ω}_{0} t ) {\int }_{- π}^{π} \vert {m}_{j} \vert cos n {ω}_{0} t d {ω}_{0} t + sin ( n {ω}_{0} t ) {\int }_{- π}^{π} \vert {m}_{j} \vert sin n {ω}_{0} t d {ω}_{0} t )$$

Where, mⱼ, j=a, b, c, represents the modulation wave of phase a, b, or c; a₀ denotes the first term of the Fourier series expansion; N is the order of the expansion, and n is the order index; t represents time; ω₀=2πf₀, where f₀ is the fundamental frequency, and π represents the mathematical constant pi; Sⱼₚₙ, j=a, b, c represents the switching function for modulating the current of phase a, b, or c.

In the second aspect, this disclosure provides an electronic device. The electronic device includes at least one memory for storing programs; and at least one processor for executing the programs stored in the memory. When the programs stored in the memory are executed, the processor is configured to perform the method described in the first aspect or any possible implementation of the first aspect.

In the third aspect, this disclosure provides a computer-readable storage medium. The computer-readable storage medium stores a computer program. When the computer program is executed on a processor, the processor performs the method described in the first aspect or any possible implementation of the first aspect.

In summary, compared with related arts, the technical solution in this disclosure has the following advantages:

The disclosure proposes a method for the differentiating method of mathematical model of three-level converter considering neutral point dynamics. The mathematical model of the three-level converter constructed by this method not only accurately reflects the dynamic characteristics of the three-level neutral point, but also, through expanding the model using Fourier series, makes the neutral point dynamics of the three-level converter differentiable and easier to linearize. This makes the model more suitable for stability analysis of power-electronized power systems.

### BRIEF DESCRIPTION OF THE DRAWINGS

FIG. 1 is a schematic diagram of the process for a differentiating method of mathematical model of three-level converter considering neutral point dynamics, as provided in an embodiment of this application.

FIG. 2 is a comparison diagram of the neutral point dynamics after disturbance between the differentiable model proposed in this application and the original model, as provided in an embodiment of this application.

FIG. 3 is a schematic diagram of the structural composition of an electronic device, as provided in an embodiment of this disclosure.

### DESCRIPTION OF THE EMBODIMENTS

In order for the objectives, technical solutions, and advantages of the disclosure to be more comprehensible, the disclosure is further described in detail below in conjunction with the embodiments accompanied with drawings. It should be understood that the specific embodiments described herein are only used to describe the disclosure and are not used to limit the disclosure.

In the embodiments of the disclosure, words such as “exemplary” or “for example” are used to indicate examples, illustrations, or descriptions. Any embodiment or design described as “exemplary” or “for example” in the embodiments of the disclosure should not be construed as being preferred or advantageous over other embodiments or designs. Specifically, the use of words such as “exemplary” or “for example” are intended to present relevant concepts in a specific manner.

In the description of the embodiments of the disclosure, unless otherwise specified, the meaning of “multiple” refers to two or more than two. For example, multiple processing units refers to two or more processing units, etc., and multiple elements refers to two or more elements, etc.

The technical solutions provided in the embodiments of the disclosure are introduced below.

### Embodiment 1

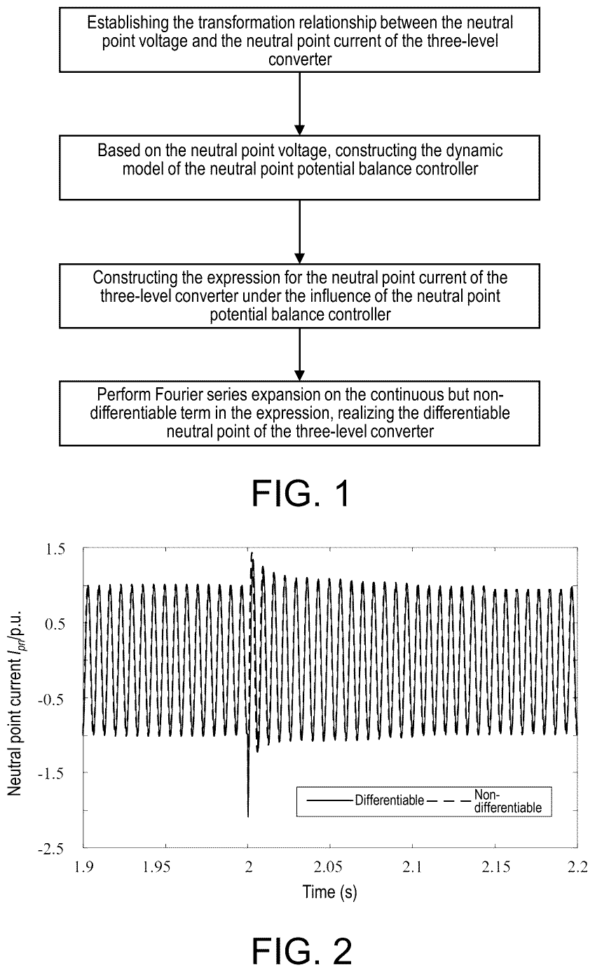

As shown in FIG. 1, embodiment 1 includes the following steps:

S1: establishing the transformation relationship between the neutral point voltage and the neutral point current of the three-level converter;

The transformation relationship between the neutral point voltage uₚₙ and the neutral point current iₚₙ is specifically:

$${\dot{u}}_{pn} = \frac{{i}_{pn}}{{C}_{p} + {C}_{n}}$$

Where \dot{u}ₚₙ represents the derivative of the neutral point voltage uₚₙ, and Cₚ+Cₙ represents the sum of the capacitance values of the upper and lower levels of the three-level converter.

S2: Based on the neutral point voltage, establishing the dynamic model of the neutral point potential balance controller.

After obtaining the neutral point voltage uₚₙ, the dynamic model of the neutral point potential balance controller is constructed as follows:

$${m}_{0} = \frac{( {k}_{ipn} ( 0 - {u}_{pn} ) + {x}_{v} )}{{u}_{dc}}$$

Where m₀ is the output of the neutral point potential balance controller; u_{dc} is the sum of the upper and lower level voltages of the three-level converter; \dot{x}ᵥ represents the output of the PI integral controller, \dot{x}ᵥ=kₚₚₙ(0−uₚₙ), and xᵥ is derived from \dot{x}ᵥ. kₚₚₙ and kᵢₚₙ are the proportional gain coefficient and the integral adjustment coefficient of the neutral point potential balance controller, respectively.

S3: Based on the influence of the neutral point potential balance controller, constructing the expression for the neutral point current of the three-level converter as follows:

$${i}_{pn} = {\sum }_{j = a , b , c} ( 1 - \vert {m}_{j} \vert ) {i}_{j} - \frac{6}{π} {m}_{0} \sqrt{{i}_{d}^{2} + {i}_{q}^{2}} cos φ$$

where i_{d} represents the D-axis output current of the three-level converter, i_{q} represents the Q-axis output current of the three-level converter; iⱼ, j=a, b, c represents the output current of phase a, b, or c of the three-level converter; π is the mathematical constant pi; φ is the power factor angle; and mⱼ, j=a, b, c represents the modulation wave of phase a, b, or c of the three-level converter, which is a continuous but non-differentiable term.

S4: Expanding the three-phase modulation waves using Fourier series as follows:

$$\vert {m}_{j} \vert \approx {S}_{jpn} = \frac{{a}_{0}}{2} + \frac{1}{π} {\sum }_{n = 1}^{N} ( cos ( n {ω}_{0} t ) {\int }_{- π}^{π} \vert {m}_{j} \vert cos n {ω}_{0} t d {ω}_{0} t + sin ( n {ω}_{0} t ) {\int }_{- π}^{π} \vert {m}_{j} \vert sin n {ω}_{0} t d {ω}_{0} t )$$

Where mⱼ, j=a, b, c, represents the modulation wave of phase a, b, or c; a₀ represents the first term of the Fourier series expansion; N is the order of the expansion, and n is the order index; t represents time; ω₀=2πf₀, where f₀ is the fundamental frequency, π represents the mathematical constant pi, d represents the derivative, and Sⱼₚₙ, j=a, b, c represents the switching function for modulating the current of phase a, b, or c.

mⱼ can be expressed as the following equation under balanced conditions:

$$\{ \begin{matrix}{m}_{a} = m cos ( ω t - φ ) \\ {m}_{b} = m cos ( ω t - φ - \frac{2 π}{3} ) \\ {m}_{c} = m cos ( ω t - φ + \frac{2 π}{3} ) \\ ω t = {θ}_{pll} + {ω}_{0} t\end{matrix}$$

Where θₚₗₗ is the phase-locked angle output, and m is the amplitude of the modulation wave. Since the period of cos(ωt−φ) is π, while the period of cos nθ is π/n, the integral over the interval [−π, π] benefits from periodicity. The zero-crossing points of cos(ωt−φ) within the integration interval are

$$( - \frac{π}{2} + φ - {ω}_{0} t ) and ( \frac{π}{2} + φ - {ω}_{0} t ) .$$

By integrating the modulation wave over the interval

$$[ - \frac{π}{2} + φ - {ω}_{0} t , \frac{π}{2} + φ - {ω}_{0} t ] ,$$

the three-phase modulation waves are calculated as follows:

$$\{ \begin{matrix}{S}_{apn} = \frac{2 m}{π} + {\sum }_{n = 1}^{N} \frac{{( - 1 )}^{n} 2 m ( - 2 )}{π ( 2 n + 1 ) ( 2 n - 1 )} cos ( 2 n ( φ - ω t ) ) \\ {S}_{bpn} = \frac{2 m}{π} + {\sum }_{n = 1}^{N} \frac{{( - 1 )}^{n} 2 m ( - 2 )}{π ( 2 n + 1 ) ( 2 n - 1 )} cos ( 2 n ( φ - ω t + \frac{2 π}{3} ) ) \\ {S}_{cpn} = \frac{2 m}{π} + {\sum }_{n = 1}^{N} \frac{{( - 1 )}^{n} 2 m ( - 2 )}{π ( 2 n + 1 ) ( 2 n - 1 )} cos ( 2 n ( φ - ω t - \frac{2 π}{3} ) )\end{matrix}$$

Sₐₚₙ represents the switching function for phase a, S_{bpn} represents the switching function for phase b, and S_{cpn} represents the switching function for phase c.

Where N=2K. In this embodiment, K is taken as 15, so the mathematical model of the three-level converter is as follows:

$$\{ \begin{matrix}{\dot{u}}_{pn} = \frac{{i}_{pn}}{{C}_{p} + {C}_{n}} \\ {\dot{x}}_{v} = {k}_{ppn} ( 0 - {u}_{pn} ) \\ {m}_{0} = \frac{( {k}_{ipn} ( 0 - {u}_{pn} ) + {x}_{v} )}{{u}_{dc}} \\ {i}_{pn} = {\sum }_{j = a , b , c} ( 1 - {S}_{jpn} ) {i}_{j} - \frac{6}{π} {m}_{0} \sqrt{{i}_{d}^{2} + {i}_{q}^{2}} cos φ \\ {S}_{jpn} = \frac{2 m}{π} + {\sum }_{n = 1}^{K} \frac{{( - 1 )}^{n} 2 m ( - 2 )}{π ( 2 n + 1 ) ( 2 n - 1 )} cos ( 2 n ( φ - ω t - {δ}_{j} ) ) \\ [ \begin{matrix}{δ}_{a} & {δ}_{b} & {δ}_{c}\end{matrix} ] = [ \begin{matrix}0 & - \frac{2 π}{3} & \frac{2 π}{3}\end{matrix} ]\end{matrix}$$

Where j=a, b or c.

A differentiable mathematical model of the three-level converter is constructed in Matlab/Simulink simulation software to verify the accuracy of the proposed differentiation method in this application. To demonstrate the precision of this model, the dynamic characteristics of the constructed differentiable model and the original nonlinear model are compared under the same parameters. The original nonlinear model is expressed as follows:

$$\{ \begin{matrix}{\dot{u}}_{pn} = \frac{{i}_{pn}}{{C}_{p} + {C}_{n}} \\ {\dot{x}}_{v} = {k}_{ppn} ( 0 - {u}_{pn} ) \\ {m}_{0} = \frac{( {k}_{ipn} ( 0 - {u}_{pn} ) + {x}_{v} )}{{u}_{dc}} \\ {i}_{pn} = {\sum }_{j = a , b , c} ( 1 - \vert {m}_{j} + {m}_{0} \vert ) {i}_{j}\end{matrix}$$

Based on the constructed model, the system operates for 2 seconds under rated conditions, then a disturbance is introduced (the voltage reference value reduce to 5%). The dynamic response of the neutral point voltage in the proposed differentiable model and the original nonlinear model is compared, as shown in FIG. 2.

As shown in FIG. 2, after being disturbed, the neutral point voltage of the inverter oscillates and rapidly decays, and the system stabilizes within 0.5 seconds. By comparing the simulation results of the original nonlinear model with the calculated results of the proposed differentiable method in this application, it is evident that the proposed differentiating method can achieve system differentiability and accurately reflects the dynamic behavior of the neutral point in the original model.

The method proposed in this disclosure achieves model differentiability by performing Fourier series expansion on non-differentiable terms in the model, exhibiting strong scalability. This differentiating method can be extended to neutral-point-clamped three-level inverters, T-type three-level inverters, LCC converters using semi-controlled devices, and other power electronic equipment with non-differentiable characteristics.

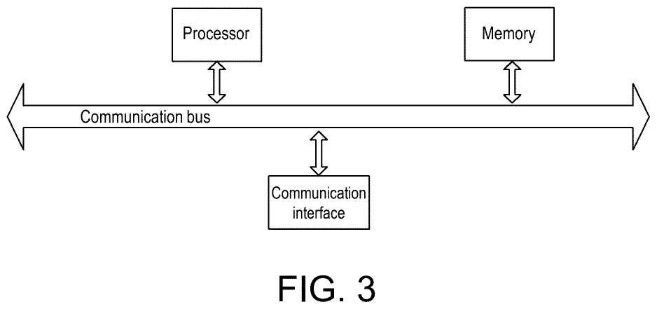

Based on the method in the above embodiment, an embodiment of the disclosure provides an electronic device, as shown in FIG. 3. The electronic device may include a processor, a communication interface, a memory, and a communication bus. The processor, the communication interface, and the memory communicate with each other through the communication bus. The processor may call logic instructions in the memory to execute the method in the above embodiment.

In addition, the logic instructions in the above memory may be implemented in a form of a software functional unit and may be stored in a computer-readable storage medium when sold or used as an independent product. Based on such an understanding, the technical solution in the disclosure, a part that contributes to the related art, or a part of the technical solution may be embodied in a form of a software product. The computer software product is stored in a storage medium and includes several instructions for enabling a computer device (which may be a personal computer, a server, a network device, etc.) to execute all or a part of the steps of the method described in each of the embodiments of the disclosure.

Based on the method in the above embodiment, an embodiment of the disclosure provides a computer-readable storage medium, and the computer-readable storage medium stores a computer program. When the computer program runs on the processor, the processor executes the method in the above embodiment.

Based on the method in the above embodiment, an embodiment of the disclosure provides a computer program product. When the computer program product runs on the processor, the processor executes the method in the above embodiment.

It may be understood that the processor in the embodiment of the disclosure may be a central processing unit (CPU), or may further be other general-purpose processors, digital signal processors (DSP), application specific integrated circuits (ASIC), field programmable gate arrays (FPGA), or other programmable logic devices, transistor logic devices, hardware components or any combination thereof. The general-purpose processor may be a microprocessor or any conventional processor.

The steps of the method in the embodiment of the disclosure may be implemented by hardware, or by the processor executing software instructions. The software instructions may be composed of corresponding software modules. The software modules may be stored in a random access memory (RAM), flash memory, read-only memory (ROM), programmable ROM (PROM), erasable PROM (EPROM), electrically EPROM (EEPROM), register, hard disk, mobile hard disk, CD-ROM, or any other form of storage medium known in the art. An exemplary storage medium is coupled to the processor, so that the processor may read information from, and write information to, the storage medium. Of course, the storage medium may also be an integral part of the processor. The processor and the storage medium may reside in the ASIC.

In the above embodiments, all or a part of the embodiments may be implemented by software, hardware, firmware, or any combination thereof. When implemented using the software, all or a part of the embodiments may be implemented in a form of the computer program product. The computer program product includes one or more computer instructions. When the computer program instructions are loaded and executed on a computer, all or a part of processes or functions described in the embodiment of the disclosure are generated. The computer may be a general-purpose computer, a special-purpose computer, a computer network, or other programmable device. The computer instructions may be stored in the computer-readable storage medium or transmitted through the computer-readable storage medium. The computer instructions may be transmitted from one website, computer, server, or data center to another website, computer, server, or data center in wired (e.g., a coaxial cable, an optical fiber, a digital subscriber line (DSL)) or wireless (e.g., infrared, wireless, microwave, etc.) manner. The computer-readable storage medium may be any available medium that may be accessed by the computer or a data storage device such as the server or the data center that includes one or more available media. The available medium may be a magnetic medium (e.g., a floppy disk, a hard disk, a magnetic tape), an optical medium (e.g., a DVD), or a semiconductor medium (e.g., a solid state disk (SSD)).

It should be understood that various reference numerals involved in the embodiments of the disclosure are only used for the convenience of description and are not used to limit the scope of the embodiments of the disclosure.

It will be easily understood by those skilled in the art that the above description is only a preferred embodiment of the disclosure and is not intended to limit the disclosure. Any modifications, equivalent substitutions, and improvements made within the spirit and principles of the disclosure shall be included in the scope of the disclosure.

What is claimed is:

1. A differentiating method of mathematical model of three-level converter considering neutral point dynamics, comprising:
establishing a transformation relationship between neutral point voltage and a neutral point current of a three-level converter;
based on the neutral point voltage, establishing a dynamic model of a neutral point potential balance controller;
constructing an expression for the neutral point current of the three-level converter under an influence of the neutral point potential balance controller; and
expanding the expression using Fourier series to achieve differentiability of a neutral point in the three-level converter.

2. The differentiating method of mathematical model of three-level converter according to claim 1, wherein the transformation relationship between the neutral point voltage and the neutral point current of the three-level converter is that a derivative of the neutral point voltage is equal to the neutral point current divided by a sum of capacitance values of an upper level and a lower capacitor of the three-level converter.

3. The differentiating method of mathematical model of three-level converter according to claim 1, wherein the neutral point potential balance controller generates a compensation amount through a PI operation based on a neutral point potential error, and then superimposes the compensation amount onto a modulation wave to achieve neutral point potential balance control.

4. The differentiating method of mathematical model of three-level converter according to claim 1, wherein the expression for the neutral point current of the three-level converter is constructed based on an output current of the three-level converter, an output of the neutral point potential balance controller, a three-phase modulation wave, and a power factor angle.

5. The differentiating method of mathematical model of three-level converter according to claim 1, wherein a three-phase modulation wave in the expression for the neutral point current of the three-level converter is expanded using Fourier series to achieve differentiability of the neutral point in the three-level converter.

6. The differentiating method of mathematical model of three-level converter according to claim 1, wherein the dynamic model of neutral point potential balance controller is as follows:
$${m}_{0} = \frac{( {k}_{ipn} ( 0 - {u}_{pn} ) + {x}_{v} )}{{u}_{dc}}$$
where m₀ represents an output of the neutral potential balance controller; \dot{x}ᵥ represent an output of a PI integral controller, \dot{x}ᵥ=kₚₚₙ(0−uₚₙ), \dot{x}ᵥ represent a derivative of xᵥ; uₚₙ represent a neutral voltage, and u_{dc} represent a DC voltage, wherein kₚₚₙ represent a proportional gain coefficient of neutral potential balance control, and kᵢₚₙ represent an integral adjustment coefficient of the neutral potential balance control.

7. The differentiating method of mathematical model of three-level converter according to claim 1, wherein the expression of the neutral point current iₚₙ of the three-level converter is as follows:
$${i}_{pn} = {\sum }_{j = a , b , c} ( 1 - \vert {m}_{j} \vert ) {i}_{j} - \frac{6}{π} {m}_{0} \sqrt{{i}_{d}^{2} + {i}_{q}^{2}} cos φ$$
where, i_{d} represents an output current of a D-axis of the three-level converter, and i_{q} represents an output current of a Q-axis of the three-level converter, wherein iⱼ, j=a, b, c represents an output current of a phase a, b, or c of the three-level converter; π is PI; φ is a power factor angle; mⱼ, j=a, b, c represents an a, b, or c phase modulation wave of the three-level converter; m₀ represents an output of the neutral potential balance controller.

8. The differentiating method of mathematical model of three-level converter according to claim 1, wherein expanding Fourier series on the three-phase modulation wave in the expression, specifically, expanding the three-phase modulation wave using Fourier series:
$$\vert {m}_{j} \vert \approx {S}_{jpn} = \frac{{a}_{0}}{2} + \frac{1}{π} {\sum }_{n = 1}^{N} ( cos ( n {ω}_{0} t ) {\int }_{- π}^{π} \vert {m}_{j} \vert cos n {ω}_{0} t d {ω}_{0} t + sin ( n {ω}_{0} t ) {\int }_{- π}^{π} \vert {m}_{j} \vert sin n {ω}_{0} t d {ω}_{0} t )$$
where, mⱼ, j=a, b, c, represents a modulation wave of a phase a, b, or c; a₀ represents a first term of a Fourier series expansion; N is an order of the Fourier series expansion, and n is an order index; t represents time; ω₀=2πf₀, where f₀ is the a fundamental frequency, and π represents the mathematical constant pi; Sⱼₚₙ, j=a, b, c represents a switching function for modulating a current of the phase a, b, or c.

9. An electronic device, comprising:
at least one memory for storing a computer program;
at least one processor for performing the differentiating method stored in the memory, wherein when the program stored in the memory is executed, the processor is configured to perform the method according to claim 1.

10. A computer-readable storage medium, wherein that the computer-readable storage medium stores a computer program, and when the computer program is executed on a processor, the processor is caused to performs the differentiating method according to claim 1.
